(19) United States
(12) Patent Application Publication
(10) Pub. No.: US 2026/0215169 A1
(43) Pub. Date: Jul. 23, 2026

(54) SELF-SELECTING MEMORY DEVICE INCLUDING CHALCOGENIDE MATERIAL AND METHOD OF MANUFACTURING THE SAME

(71) Applicant: SAMSUNG ELECTRONICS CO., LTD., Suwon-si (KR)

(72) Inventors: Jinwoo LEE, Suwon-si (KR); Hyunsang HWANG, Pohang-si (KR); Yoori SEO, Pohang-si (KR); Jangseop LEE, Pohang-si (KR); Dongho AHN, Suwon-si (KR); Minseo YOON, Suwon-si (KR); Jinmyung CHOI, Suwon-si (KR); Hideki HORII, Suwon-si (KR)

(73) Assignees: SAMSUNG ELECTRONICS CO., LTD., Suwon-si (KR); POSTECH RESEARCH AND BUSINESS DEVELOPMENT FOUNDATION, Pohang-si (KR)

(21) Appl. No.: 19/341,344

(22) Filed: Sep. 26, 2025

(30) Foreign Application Priority Data
Jan. 21, 2025 (KR) 10-2025-0008854

(51) Int. Cl. H10N 70/00; H10B 63/00

(52) U.S. Cl. CPC H10N 70/021; H10B 63/24; H10B 63/84; H10N 70/841; H10N 70/8825; H10N 70/8828

(57) ABSTRACT

Provided is a method of manufacturing a memory device, the method including preparing a first electrode, forming a chalcogenide structure on the first electrode, and forming a second electrode on the chalcogenide structure, wherein the forming of the chalcogenide structure includes a first operation of depositing a chalcogenide layer and a second operation of performing an ultraviolet treatment on the deposited chalcogenide layer, and wherein the first operation and the second operation are repeatedly performed until the chalcogenide structure has a particular thickness.

### CROSS-REFERENCE TO RELATED APPLICATION

This application is based on and claims priority under 35 U.S.C. § 119 to Korean Patent Application No. 10-2025-0008854, filed on Jan. 21, 2025, in the Korean Intellectual Property Office, the disclosure of which is incorporated by reference herein in its entirety.

### BACKGROUND

The present disclosure relates to a self-selecting memory device including a chalcogenide material and a method of manufacturing the self-selecting memory device, and more particularly, to a self-selecting memory device including an ultraviolet (UV)-treated chalcogenide material and a method of manufacturing the self-selecting memory device.

Recently, due to the miniaturization, low power, high performance, diversification, or the like of electronic devices, semiconductor devices capable of storing information in various electronic devices, such as computers and portable communication devices, are required, and research on this issue is being conducted. These semiconductor devices include semiconductor devices capable of storing data by using characteristics of switching between different resistance states according to applied voltage or current, such as resistive random access memory (RRAM), phase-change RAM (PRAM), ferroelectric RAM (FRAM), magnetic RAM (MRAM), and E-fuse.

### SUMMARY

The present disclosure provides a self-selecting memory device including a chalcogenide structure formed by performing an ultraviolet (UV) treatment by using a split process.

The present disclosure provides a method of manufacturing a self-selecting memory device including a chalcogenide structure formed by performing the UV treatment by using the split process.

However, the issues to be solved by the present disclosure are not limited to those described above, and other issues may be clearly understood by those of skill in the art from the following descriptions.

According to an aspect of the present disclosure, there is provided a method of manufacturing a memory device, the method including preparing a first electrode, forming a chalcogenide structure on the first electrode, and forming a second electrode on the chalcogenide structure, wherein the forming of the chalcogenide structure includes a first operation of depositing a chalcogenide layer and a second operation of performing a UV treatment on the deposited chalcogenide layer, and wherein the first operation and the second operation are repeatedly performed until the chalcogenide structure has a particular thickness.

According to another aspect of the present disclosure, there is provided a method of manufacturing a memory device, the method including preparing a first electrode, forming a first buffer layer on the first electrode, forming a chalcogenide structure having ovonic threshold switching characteristics on the first buffer layer, forming a second buffer layer on the chalcogenide structure, and forming a second electrode on the second buffer layer, wherein the forming of the chalcogenide structure includes a first operation of depositing a chalcogenide layer and a second operation of performing a UV treatment on the deposited chalcogenide layer, and wherein the first operation and the second operation are repeatedly performed until the chalcogenide structure has a particular thickness.

According to another aspect of the present disclosure, there is provided a memory device including a first electrode, a first buffer layer on the first electrode, a chalcogenide structure on the first buffer layer, a second buffer layer on the chalcogenide structure, and a second electrode on the second buffer layer, wherein the chalcogenide structure includes a plurality of chalcogenide layers, and each of the plurality of chalcogenide layers is UV treated. In the memory device, in an interatomic bonding of each of the plurality of chalcogenide layers, a number of heteropolar bonds on a surface of each of the plurality of chalcogenide layers is greater than a number of heteropolar bonds inside each of the plurality of chalcogenide layers.

### BRIEF DESCRIPTION OF DRAWINGS

Embodiments will be more clearly understood from the following detailed description taken in conjunction with the accompanying drawings in which:

FIG. 1 is a diagram of a memory device according to an embodiment;

FIG. 2 is a flowchart of a method of manufacturing a memory device, according to an embodiment;

FIGS. 3 through 5 are diagrams of a method of manufacturing a memory device, according to embodiments;

FIG. 6 is a diagram of a forming voltage reduction effect of a chalcogenide structure, according to an embodiment;

FIG. 7A is a diagram of band-gap energy of a chalcogenide structure according to an embodiment;

FIG. 7B is a diagram of activation energy of a chalcogenide structure according to an embodiment;

FIG. 8 is a diagram of variability of a chalcogenide structure, according to an embodiment;

FIG. 9 is a diagram of drift characteristics of a chalcogenide structure, according to an embodiment;

FIGS. 10A, 10B, and 10C are diagrams of set operations and reset operations of a memory device, according to embodiments;

FIG. 11 is a diagram of a relatively wide memory window securing effect of a memory device, according to an embodiment;

FIGS. 12A and 12B are diagrams of drift characteristics of a memory device, according to embodiments;

FIGS. 13A and 13B are diagrams of high temperature drift characteristics of a memory device, according to embodiments;

FIGS. 14A and 14B are diagrams of read disturb characteristics of a memory device, according to embodiments;

FIGS. 15A and 15B are diagrams of changes in material characteristics on a surface when an ultraviolet (UV) treatment is performed for a relatively long time, according to embodiments;

FIGS. 16A, 16B, 16C, and 16D are diagrams of changes in material characteristics inside a memory device when the UV treatment is performed for a relatively long time and a relatively short time, according to embodiments;

FIGS. 17A and 17B are diagrams of a binding energy increase of a chalcogenide structure, according to embodiments;

FIG. 18 is a schematic perspective view of a structure of a memory device, according to an embodiment;

FIG. 19 is a schematic perspective view of a structure of a memory device, according to an embodiment; and

FIG. 20 is a schematic vertical cross-section view of a configuration of one memory cell in the memory device illustrated in FIG. 19.

### DETAILED DESCRIPTION OF EMBODIMENTS

Hereinafter, embodiments of the present disclosure are described in detail with reference to the accompanying drawings. Identical reference numerals are used for the same constituent elements in the drawings, and duplicate descriptions thereof are omitted.

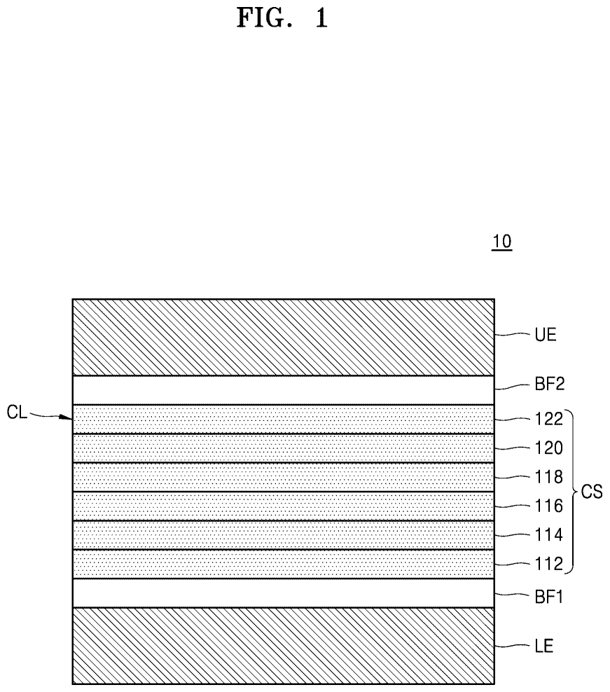

FIG. 1 is a diagram of a memory device 10 according to an embodiment.

Referring to FIG. 1, the memory device 10 may include a first electrode LE, a second electrode UE apart from the first electrode LE and facing the first electrode LE, and a chalcogenide structure CS arranged between the first electrode LE and the second electrode UE. The chalcogenide structure CS may include first, second, third, fourth, fifth, and sixth chalcogenide layers 112, 114, 116, 118, 120, and 122. In addition, the chalcogenide structure CS may include a first buffer layer BF1 arranged between the first electrode LE and the chalcogenide structure CS and a second buffer layer BF2 arranged between the second electrode UE and the chalcogenide structure CS.

The first electrode LE and the second electrode UE may apply a voltage to the chalcogenide structure CS. To this end, each of the first electrode LE and the second electrode UE may independently include a metal, a conductive metal nitride, a conductive metal oxide, or a combination thereof. For example, each of the first electrode LE and the second electrode UE may independently include titanium nitride (TiN), titanium silicon nitride (TiSiN), titanium carbon nitride (TiCN), titanium carbon silicon nitride (TiCSiN), titanium aluminum nitride (TiAlN), tantalum (Ta), tantalum nitride (TaN), tantalum silicon nitride (TaSiN), tantalum aluminum nitride (TaAlN), tungsten silicon (WSi), titanium tungsten (TiW), molybdenum nitride (MoN), niobium nitride (NbN), titanium niobium nitride (TiNbN), zirconium silicon nitride (ZrSiN), tungsten silicon nitride (WSiN), tungsten boron nitride (WBN), zirconium aluminum nitride (ZrAlN), molybdenum aluminum nitride (MoAlN), titanium aluminum (TiAl), titanium oxynitride (TiON), titanium aluminum oxynitride (TiAlON), tungsten oxynitride (WON), tantalum oxynitride (TaON), silicon carbon (SiC), silicon carbon nitride (SiCN), carbon nitride (CN), tantalum carbon nitride (TaCN), tungsten (W), tungsten nitride (WN), carbon (C), or a combination thereof. In an example, the first electrode LE may also include the same material as the second electrode UE, but is not limited thereto, and in another example, the first electrode LE and the second electrode UE may also include different materials.

The chalcogenide structure CS may have ovonic threshold switching (OTS) characteristics of having a high resistance state when a voltage lower than a threshold voltage (for example, a voltage of a lower absolute value) is applied, and having a low resistance state when a voltage higher than the threshold voltage (for example, a voltage of a higher absolute value) is applied. In addition, the chalcogenide structure CS may have characteristics of a memory in which the threshold voltage is shifted according to the polarity and intensity of the applied bias voltage. Accordingly, the chalcogenide structure CS may have characteristics of a self-selecting memory capable of performing both a memory function and a selector function by using only a single material.

The chalcogenide structure CS may include a plurality of chalcogenide layers CL. The plurality of chalcogenide layers CL may include a total of six layers, such as a first chalcogenide layer 112, a second chalcogenide layer 114, a third chalcogenide layer 116, a fourth chalcogenide layer 118, a fifth chalcogenide layer 120, and a sixth chalcogenide layer 122. However, this is an example, and the chalcogenide structure CS may not be limited to having only six layers of chalcogenide as illustrated, but may also have one to five or seven or more of chalcogenide layers.

Each of the chalcogenide layers CL may have a thickness of about 0.1 nm to about 10 nm in a vertical direction (a direction in which the second electrode UE is stacked from the first electrode LE), and may have a thickness of, for example, about 5 nm. For purposes of the present disclosure, the term “about” means ±5%.

The chalcogenide layer CL may include a chalcogenide material, and may include a single material of pluralistic system chalcogenide. Chalcogenide may include a compound including at least one chalcogen anion and at least one electropositive material, and may be used as a selection element or a phase change material depending on the type and composition ratio of constituent elements. For example, the chalcogenide layer CL may include one material of GeAsSe, GeAsSeIn, GeAsSeSb, GeAsSeSbIn, GeAsSeTe, GeAsSeIn, GeAsSeAl, GeAsSeAlIn, GeSbSe, GeSbSeIn, GeSbSeN, and GeSbSeNIn.

In the present embodiment, each component element and content included in the chalcogenide layer CL may be particularly selected to exhibit an optimal effect in overall aspects, such as device characteristics, particularly, a drift of a voltage corresponding to the reliability of a device, threshold voltage (Vth), Vth distribution, off current (Ioff), and endurance. Although any one component element and content may improve any one individual characteristic of these characteristics described above, other characteristics may be deteriorated at the same time, and thus it may be important to select the optimal component and content that may exhibit an optimal effect by maximizing the positive effects and minimizing negative effects considering the balance of all of these characteristics. In the present embodiment, each component element and content included in the chalcogenide layer CL may be determined considering the balance of each aspect of device performance in this manner.

The chalcogenide layer CL may be formed by depositing a chalcogenide material layer and then performing an ultraviolet (UV) treatment on the chalcogenide material layer. The UV treatment process may be performed for about 5 minutes to about 30 minutes, and may be performed, for example, for about 10 minutes. In addition, the UV treatment process may be performed by using a light source of about 900 W to about 1100 W within the UV wavelength range, and a mercury (Hg) electrical bulb may be used as the light source. For example, the UV treatment process may be performed by using a wavelength of about 365 nm and a light source of about 1000 W.

Because the UV treatment process causes a change in interatomic bonding only on a surface of the chalcogenide layer CL to induce a change in electrical characteristics, and the chalcogenide structure CS is formed by using a split process by forming the chalcogenide structure CS to include the plurality of chalcogenide layers CL, the change in the electrical characteristics induced by the UV treatment process may be amplified to a maximum.

In the interatomic bonding on the surface of the chalcogenide layer CL, due to the UV treatment process, the number of heteropolar bonds may be greater than that inside the chalcogenide layer CL. For example, the number of Arsenide (As)-Tellurium (Te) bonds on the surface of the chalcogenide layer CL may be greater than that inside the chalcogenide layer CL.

In addition, a binding energy value at the peak of an X-ray optoelectronic analysis graph of particular atoms constituting the surface of the chalcogenide layer CL may be different from that inside the chalcogenide layer CL. For example, the binding energy value at the peak of the X-ray optoelectronic analysis graph of As 2p_{3/2} on the surface of the chalcogenide layer CL may be less than that inside the chalcogenide layer CL. The binding energy value at the peak of the X-ray optoelectronic analysis graph of Te 3d_{5/2} on the surface of the chalcogenide layer CL may be greater than that inside the chalcogenide layer CL.

The first buffer layer BF1 and the second buffer layer BF2 may include C. The first buffer layer BF1 and the second buffer layer BF2 may have a thickness of about 3 nm to about 7 nm in the vertical direction, and for example, may have a thickness of about 5 nm. Because the memory device 10 includes the first buffer layer BF1 and the second buffer layer BF2, the conductive material of the first electrode LE and the second electrode UE may be prevented from being diffused into the chalcogenide structure CS, and thus deterioration of electrical characteristics and endurance may be prevented.

According to some embodiments, by including the UV-treated plurality of chalcogenide layers CL, the chalcogenide structure CS may provide the memory device 10 having improved electrical characteristics. For example, the memory device 10 of the present embodiment may have a relatively low forming voltage, a relatively low variability for each device, a relatively low drift characteristic, secure a relatively long retention time, and have a relatively small number of read disturb.

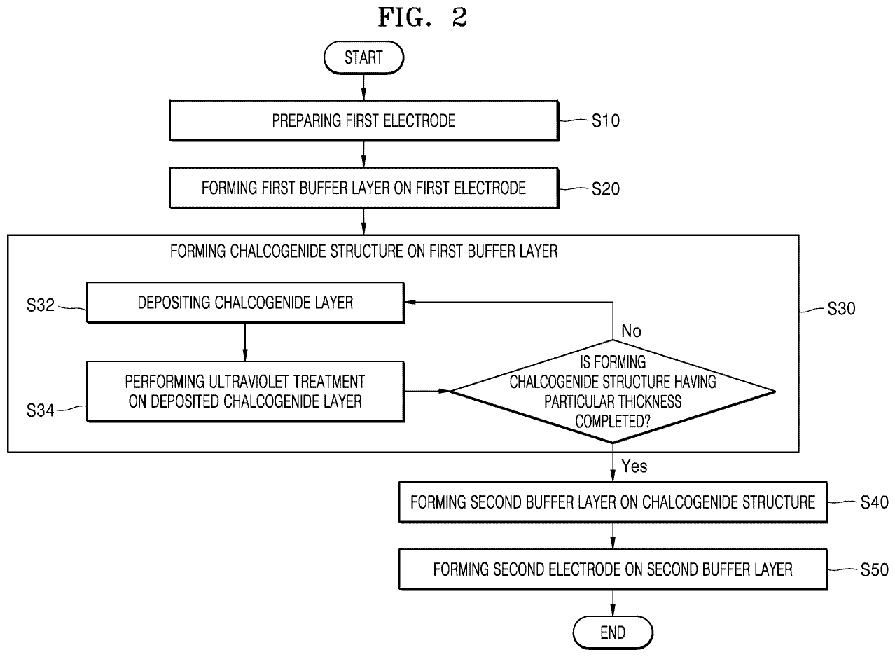

FIG. 2 is a flowchart of a method of manufacturing the memory device 10, according to an embodiment.

Referring to FIG. 2, the memory device 10 according to an embodiment may include preparing the first electrode LE (S10), forming the first buffer layer BF1 on the first electrode (S20), forming the chalcogenide structure CS on the first buffer layer BF1 (S30), forming the second buffer layer BF2 on the chalcogenide structure CS (S40), and forming the second electrode UE on the second buffer layer BF2 (S50). The forming of the chalcogenide structure CS on the first buffer layer BF1 (S30) may include depositing the chalcogenide layer CL (S32) and performing the UV treatment on the chalcogenide layer CL. The depositing of the chalcogenide layer CL (S32) and the performing of the UV treatment on the chalcogenide layer CL (S34) may be repeatedly performed until a particular thickness, e.g., a thickness or a predetermined thickness, of the chalcogenide structure CS is formed.

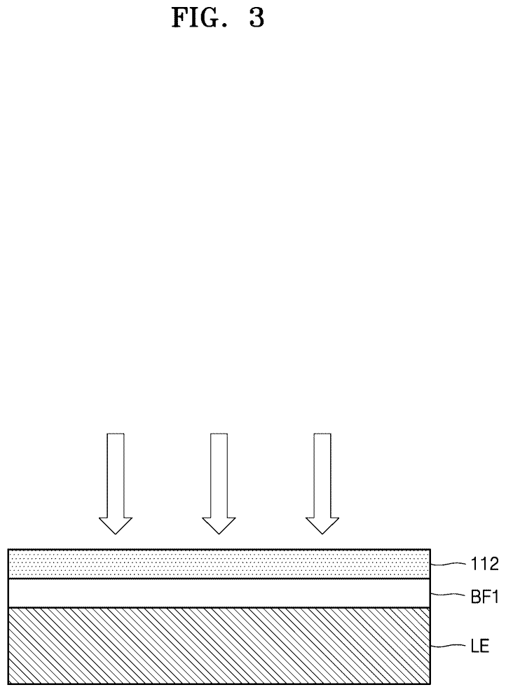

FIGS. 3 through 5 are diagrams of a method of manufacturing the memory device 10, according to embodiments.

Referring to FIG. 3, firstly, the first electrode LE may be prepared, and the first buffer layer BF1 may be formed on the first electrode LE. The first electrode LE may include a metal, a conductive metal nitride, a conductive metal oxide, or a combination thereof. The first buffer layer BF1 may include C. In some embodiments, a physical vapor deposition (PVD) process may be performed to deposit the first buffer layer BF1 on the first electrode LE.

To form the chalcogenide structure CS including the plurality of chalcogenide layers CL on the first buffer layer BF1, firstly, a chalcogenide material layer may be formed by depositing a chalcogenide material on the first buffer layer BF1, and then the chalcogenide material layer may go through the UV treatment process to form the first chalcogenide layer 112.

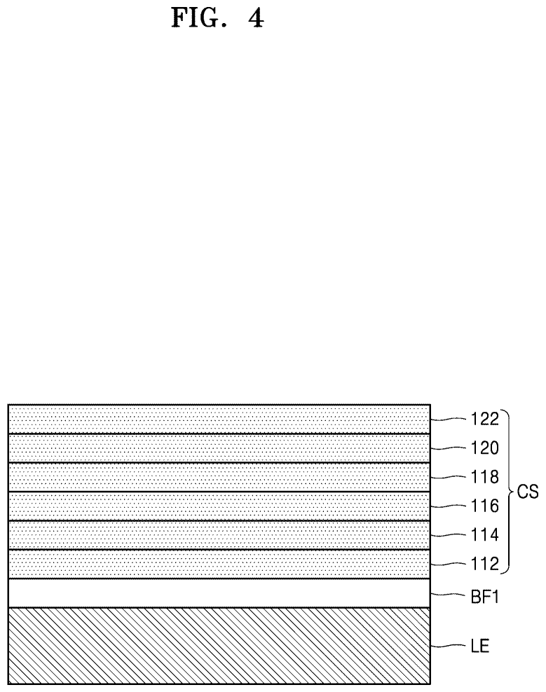

Referring to FIG. 4, a chalcogenide material layer may be formed by depositing a chalcogenide material on the first chalcogenide layer 112, and then the chalcogenide material layer may go through UV treatment to form the second chalcogenide layer 114. The deposition process of the chalcogenide material layer and the UV treatment process of the chalcogenide material layer may be repeatedly performed until the chalcogenide structure CS having a particular thickness is formed, and the chalcogenide structure CS including the plurality of chalcogenide layers CL may be formed. The deposition process of the chalcogenide material layer may be performed by, for example, a PVD process.

The UV treatment process may be performed for about 5 minutes to about 30 minutes, and may be performed, for example, for about 10 minutes. In addition, the UV treatment process may be performed by using a light source of about 900 W to about 1100 W within the UV wavelength range, and a mercury (Hg) electrical bulb may be used as the light source. For example, the UV treatment process may be performed by using a wavelength of about 365 nm and a light source of about 1000 W.

Each chalcogenide layer CL may have a thickness of about 0.1 nm to about 10 nm in the vertical direction, and may have a thickness of, for example, about 5 nm.

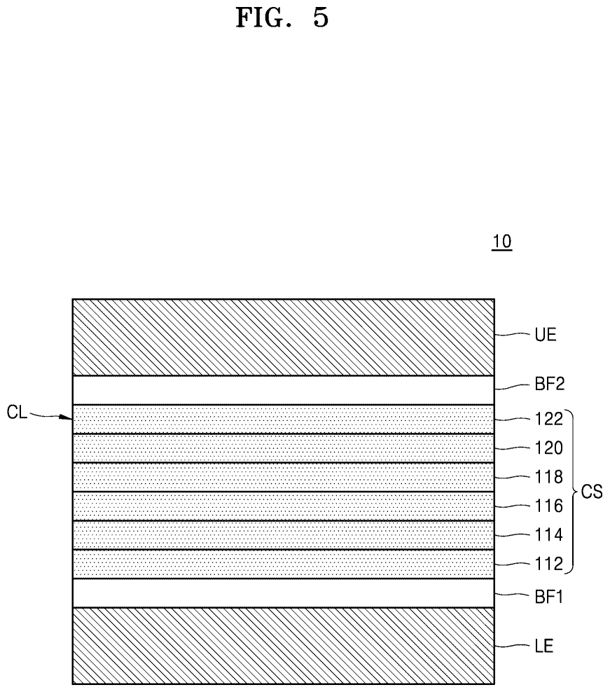

Referring to FIG. 5, the second buffer layer BF2 may be formed on the chalcogenide structure CS. The second buffer layer BF2 may include C. In some embodiments, a PVD process may be performed for deposition on the second buffer layer BF2. Thereafter, the second electrode UE may be formed on the second buffer layer BF2. The second electrode UE may include a metal, a conductive metal nitride, a conductive metal oxide, or a combination thereof.

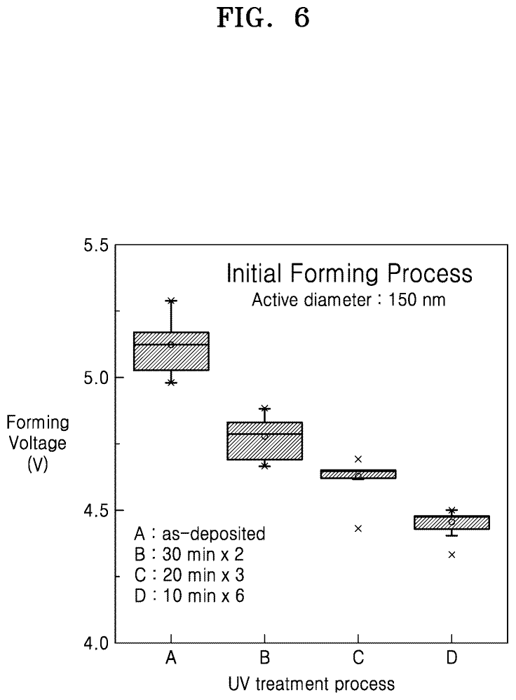

FIG. 6 is a diagram of a forming voltage reduction effect of the chalcogenide structure CS, according to an embodiment.

Referring to FIG. 6, the forming voltages may be identified for the cases when the chalcogenide structure CS is not UV-treated (A), when the chalcogenide structure CS includes two chalcogenide layers CL, and the UV treatment has been performed for about 30 minutes during the deposition process on each chalcogenide layer CL (B), when the chalcogenide structure CS includes three chalcogenide layers CL, and the UV treatment has been performed for about 20 minutes during the deposition process on each chalcogenide layer CL (C), and when the chalcogenide structure CS includes six chalcogenide layers CL, and the UV treatment has been performed for about 10 minutes during the deposition process on each chalcogenide layer CL (D).

Each chalcogenide structure CS has been manufactured at a total thickness of about 30 nm, and the thickness of the chalcogenide layer CL may be determined according to the number of layers constituting each chalcogenide structure CS. For example, when the chalcogenide structure CS includes two chalcogenide layers CL (B), the thickness of each of the chalcogenide layers may be about 15 nm, when the chalcogenide structure CS includes three chalcogenide layers CL (C), the thickness of each of the chalcogenide layers CL may be about 10 nm, and when the chalcogenide structure CS includes six chalcogenide layers (D), the thickness of each of the chalcogenide layers CL may be about 5 nm.

As illustrated in FIG. 6, as the number of cycles of UV treatment processes is increased by increasing the number of chalcogenide layers CL included in the chalcogenide structure CS, the forming voltage may decrease. When the chalcogenide structure CS includes six chalcogenide layers CL, and the UV treatment is performed for about 10 minutes during each chalcogenide layer CL deposition process (D), the forming voltage may be the least.

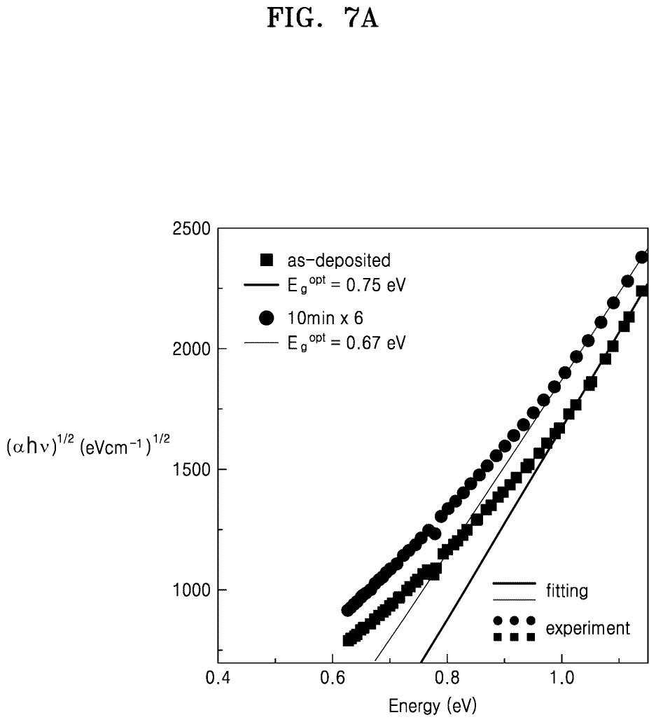

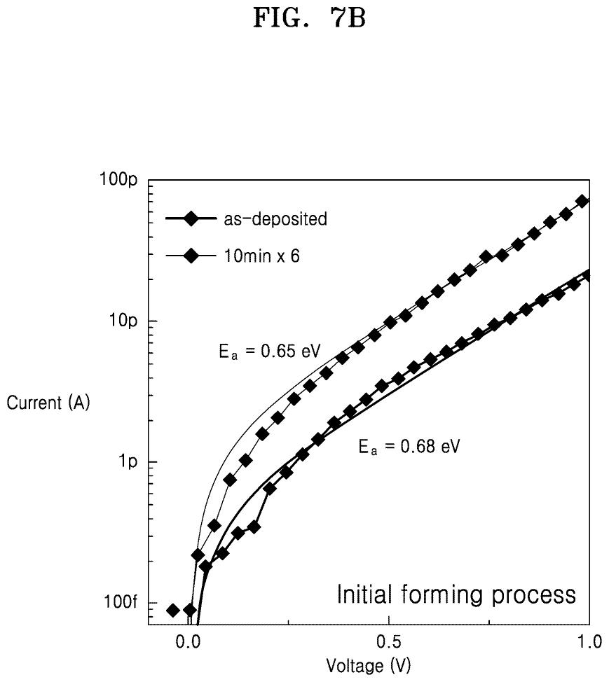

FIG. 7A is a diagram of band-gap energy of the chalcogenide structure CS, according to an embodiment.

FIG. 7B is a diagram of activation energy of the chalcogenide structure CS, according to an embodiment.

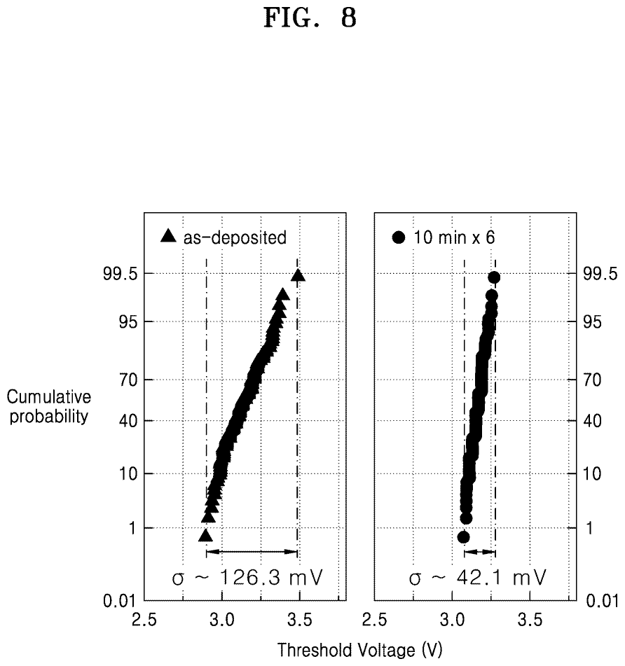

FIG. 8 is a diagram of variability of the chalcogenide structure CS, according to an embodiment.

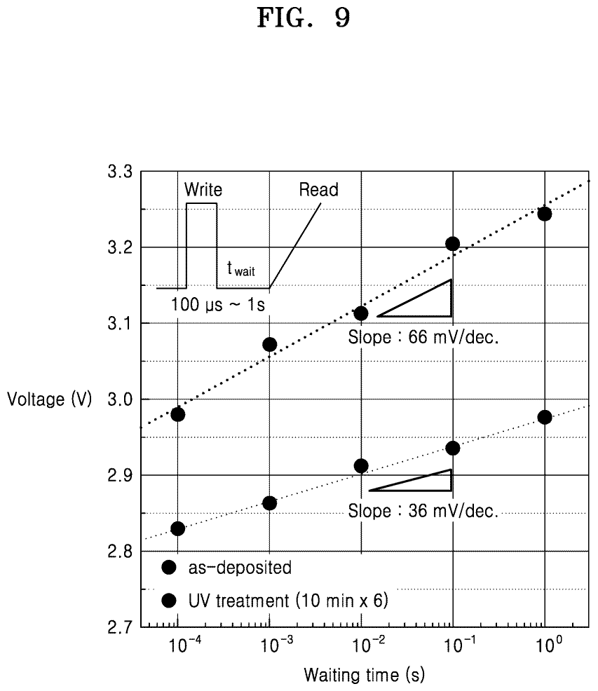

FIG. 9 is a diagram of drift characteristics of the chalcogenide structure CS, according to an embodiment.

Hereinafter, comparative examples (as-deposited) including the chalcogenide structure CS formed by using a split process without performing the UV treatment, and embodiments (10 min×6) including the chalcogenide structure CS formed by using the split process and performing the UV treatment are illustrated. In an embodiment in which the UV treatment is performed by using the split process, UV treatment for about 10 minutes has been performed at each chalcogenide layer CL deposition a total of six times to form the chalcogenide structure CS having a thickness of about 30 nm.

As illustrated in FIG. 7A, the band gap energy of the chalcogenide structure CS of the comparative example is in the range of about 0.7 to about 0.8, while the band gap energy of the chalcogenide structure CS of the embodiment is relatively reduced to about 0.6 to about 0.7.

As illustrated in FIG. 7B, the activation energy of the chalcogenide structure CS of the comparative example is about 0.68 eV, while the activation energy of the chalcogenide structure CS of the embodiment is relatively reduced to about 0.65 eV.

As illustrated in FIG. 8, the variability of the threshold voltage of the chalcogenide structure CS of the comparative example is within the range of about 126.3 mV, while the variability of the threshold voltage of the chalcogenide structure CS of the embodiment is within the range of about 42.1 mV.

Variability of a threshold voltage is the variability of the threshold voltage generated when a switching operation of a memory device is repeatedly performed. In the memory device 10, one representative cell has been selected, switching operations (on/off operations) have been repeated 100 times, the threshold voltage has been measured for each operation, and then the measured threshold voltage has been visualized in the form of a cumulative distribution curve.

As illustrated in FIG. 9, the slope of the graph of the threshold voltage change amount with respect to the waiting time of the chalcogenide structure CS of the comparative example has been about 66 mV/dec, and the slope of the graph of the threshold voltage change amount with respect to the waiting time of the chalcogenide structure CS of the embodiment has been about 36 mV/dec, which confirms that the threshold voltage change amount with respect to the waiting time for the embodiment is relatively less than that for the comparative example.

The threshold voltage change amount may be the threshold voltage change amount between a first threshold voltage and a second threshold voltage that has been identified by measuring the second threshold voltage by applying a first triangular pulse for identifying the drift characteristic of the memory device 10 to measure the first threshold voltage, by spending a certain standby time (for example, about 10⁻⁴ seconds, about 10⁻³ seconds, about 10⁻² seconds, about 10⁻¹ seconds, or about 10⁰ seconds), and then by applying a second triangular pulse. Switching experiments have been repeated thirty times for each standby time.

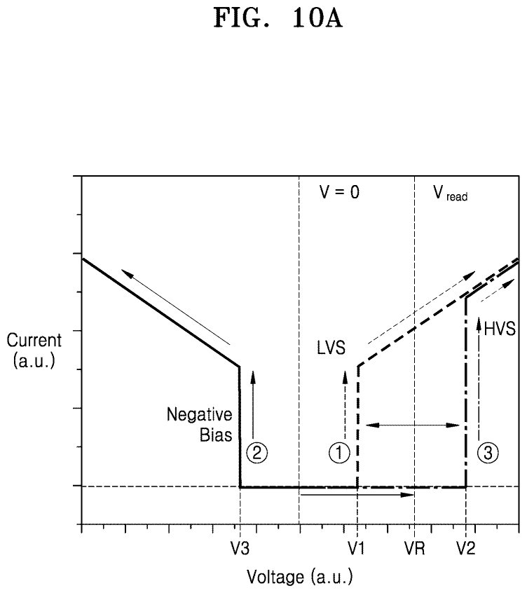

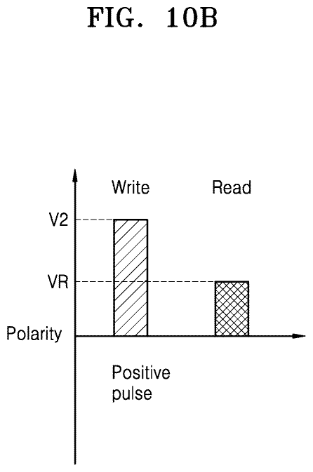

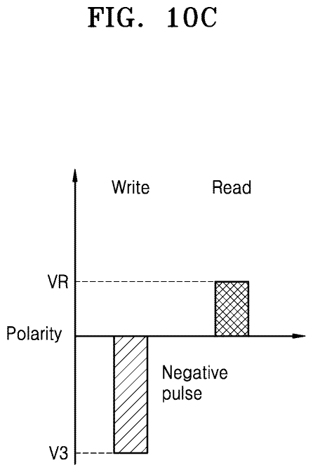

FIGS. 10A, 10B, and 10C are diagrams of set operations and reset operations of the memory device 10, according to embodiments.

Referring to FIG. 10A, the chalcogenide structure CS may have one of a first state (low threshold voltage state (LVS)) having a relatively low threshold voltage and a second state (high threshold voltage state (HVS)) having a relatively high threshold voltage. For example, the threshold voltage of the chalcogenide structure CS in the first state may be a first voltage V1, and the threshold voltage of the chalcogenide structure CS in the second state may be a second voltage V2 higher than the first voltage V1. When the chalcogenide structure CS is in the first state, and a voltage lower than the first voltage V1 is applied to the chalcogenide structure CS, little current may flow between two ends of the chalcogenide structure CS, and when a voltage higher than the first voltage V1 is applied to the chalcogenide structure CS, the chalcogenide structure CS may be turned on and current may flow through the chalcogenide structure CS. In addition, when the chalcogenide structure CS is in the second state, and a voltage lower than the second voltage V2 is applied to the chalcogenide structure CS, little current may flow between two ends of the chalcogenide structure CS, and when a voltage higher than the second voltage V2 is applied to the chalcogenide structure CS, the chalcogenide structure CS may be turned on and current may flow through the chalcogenide structure CS.

Thus, a voltage between the first voltage V1 and the second voltage V2 may be selected as a read voltage VR. When the chalcogenide structure CS is in the first state, and the read voltage VR is applied to the chalcogenide structure CS, current may flow through the chalcogenide structure CS, and in this case, a data value stored in the chalcogenide structure CS may be defined as a first binary value or a first logic value “1”. When the chalcogenide structure CS is in the second state, and the read voltage VR is applied to the chalcogenide structure CS, little current may flow through the chalcogenide structure CS, and in this case, a data value stored in the chalcogenide structure CS may be defined as a second binary value or a second logic value “0”. In other words, by measuring the current flowing in the chalcogenide structure CS while applying the read voltage VR to the chalcogenide structure CS, the data value stored in the chalcogenide structure CS may be read.

On the other hand, when the chalcogenide structure CS is in the first state, and a negative (−) bias voltage is applied to the chalcogenide structure CS, the threshold voltage of the chalcogenide structure CS may increase, and the state of the chalcogenide structure CS may be converted into the second state. For example, when a negative third voltage V3 is applied to the chalcogenide structure CS, the state of the chalcogenide structure CS may be converted into the second state. This action may be called a ‘reset’ operation or a clear operation. In the reset operation, the voltage polarity of each of the read operation and write operation has been set as reversed. In addition, when the chalcogenide structure CS is in the second state, and a positive (−) bias voltage is applied to the chalcogenide structure CS, the threshold voltage of the chalcogenide structure CS may increase, and the state of the chalcogenide structure CS may be converted into the first state. This operation may be called a ‘set’ operation or a program operation. In the set operation, the voltage polarity of each of the read operation and write operation has been set as the same.

The difference between the threshold voltage during the set operation and the threshold voltage during the reset operation may be referred to as a memory window, and the memory window measured at room temperature in the chalcogenide layer having received the UV treatment for about 10 minutes has been identified as about 1.0 V.

FIG. 10B is a graph of bias voltages for the set operation and the read operation in the memory device 10, according to an embodiment. Referring to FIG. 10B, a positive bias voltage greater than or equal to the second voltage V2 may be applied to the chalcogenide structure CS in the set operation. Then, the threshold voltage of the chalcogenide structure CS may be shifted to the first voltage V1. Thereafter, in the read operation, a positive read voltage VR between the first voltage V1 and the second voltage V2 may be applied to the chalcogenide structure CS. When the read voltage VR is applied, the chalcogenide structure CS may be turned on.

FIG. 10C is a graph of bias voltages for the reset operation and the read operation in the memory device 10, according to an embodiment. Referring to FIG. 10C, a negative bias voltage, that is, the third voltage V3 may be applied to the chalcogenide structure CS in the reset operation. The absolute value of the third voltage V3 may be approximately equal to or slightly greater than or less than the second voltage V2. Then, the threshold voltage of the chalcogenide structure CS may be shifted to the second voltage V2 which is higher than the first voltage V1. Thereafter, in the read operation, a positive read voltage VR between the first voltage V1 and the second voltage V2 may be applied to the chalcogenide structure CS. When the read voltage VR is applied, the chalcogenide structure CS may be turned off.

As described above, the chalcogenide structure CS of the memory device 10 according to the embodiment may have an ovonic threshold switching characteristic and a memory characteristic of a changing threshold voltage. In particular, the threshold voltage of the chalcogenide structure CS may be shifted according to the polarity of the bias voltage applied to the chalcogenide structure CS. In this regard, the memory device 10 according to the embodiment may include a self-selecting memory device having a polarity-dependent threshold voltage shift characteristic.

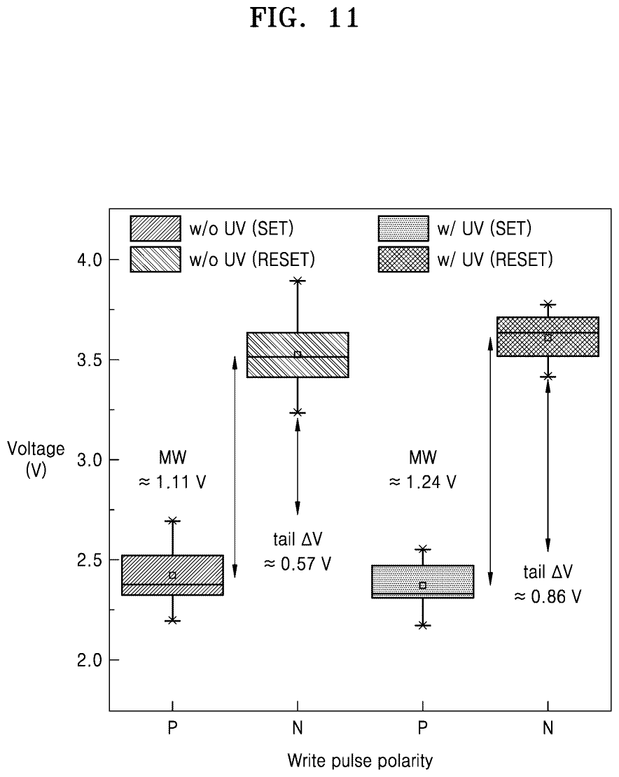

FIG. 11 is a diagram of a relatively wide memory window securing effect of the memory device 10, according to an embodiment.

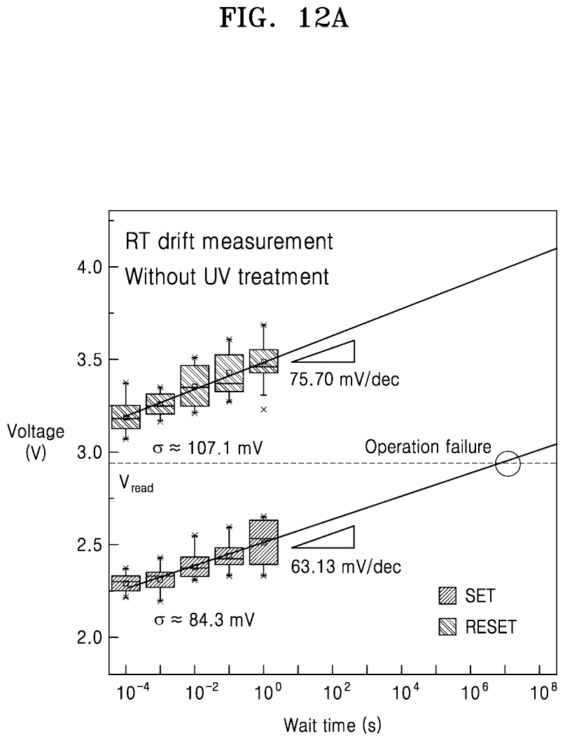

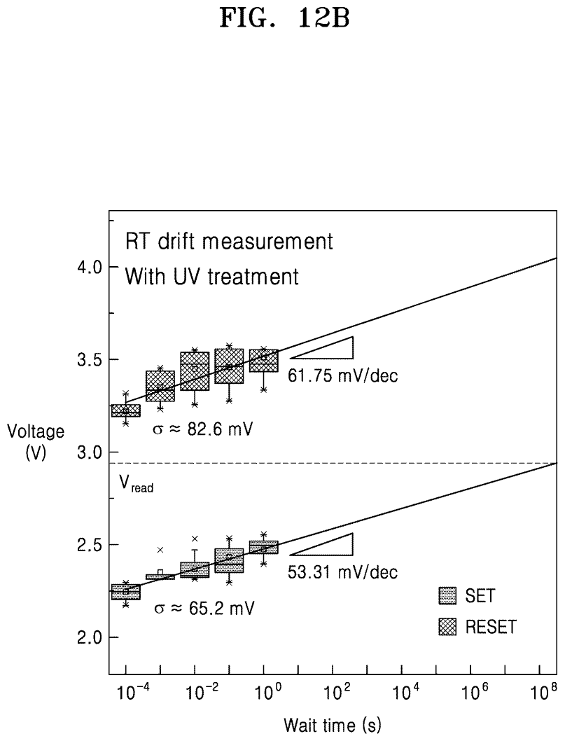

FIGS. 12A and 12B are diagrams of drift characteristics of the memory device 10, according to embodiments.

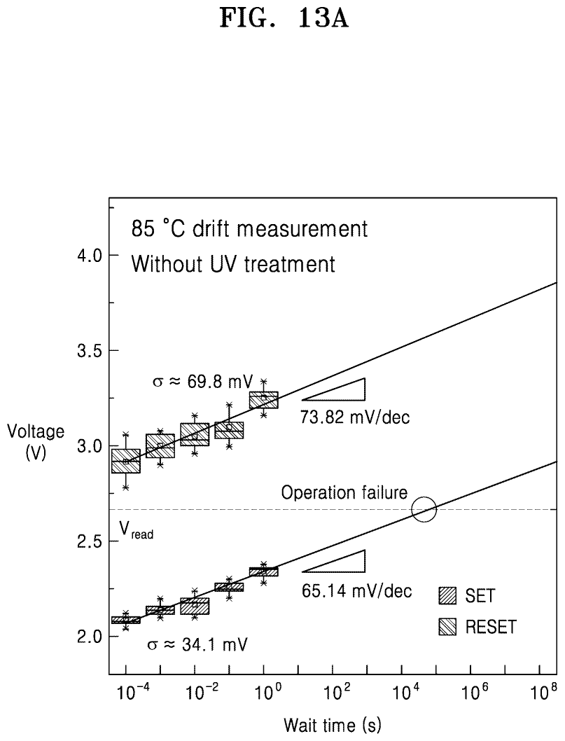

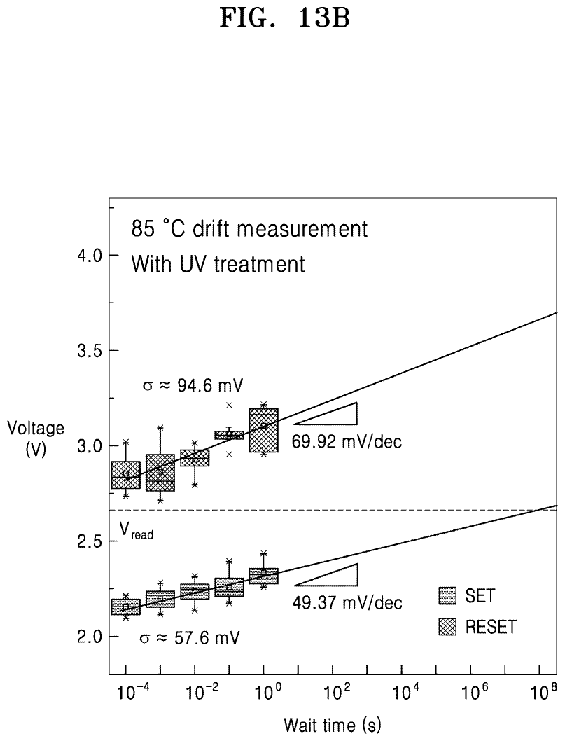

FIGS. 13A and 13B are diagrams of high temperature drift characteristics of the memory device 10, according to embodiments.

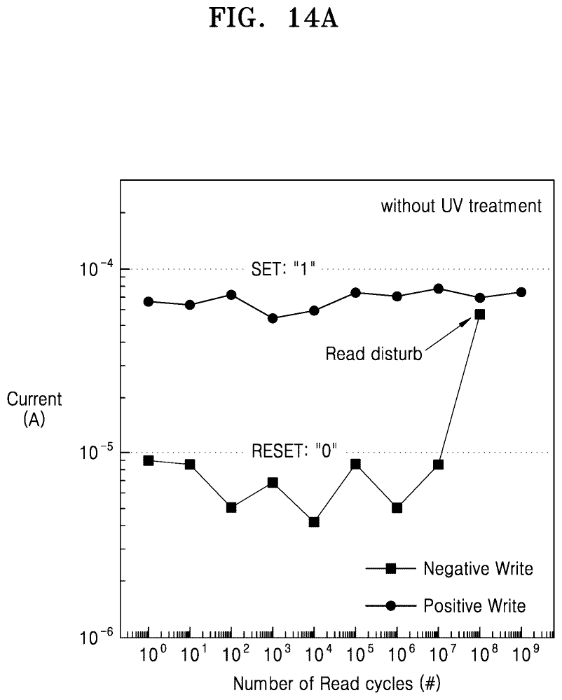

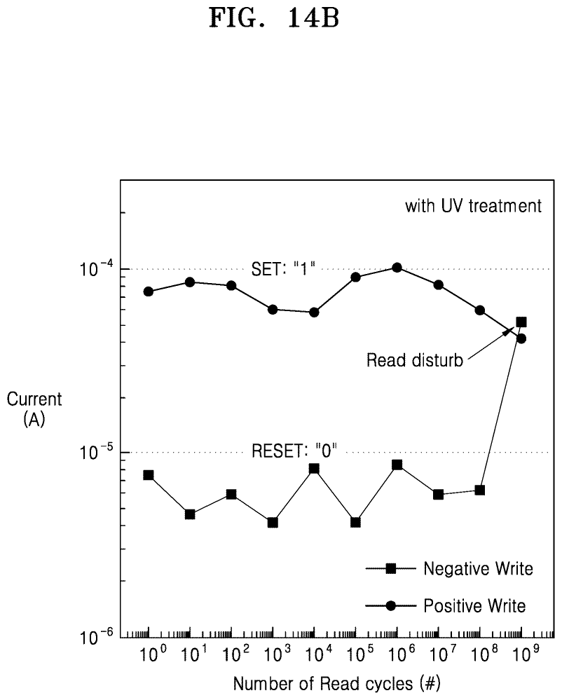

FIGS. 14A and 14B are diagrams of read disturb characteristics of the memory device 10, according to embodiments.

The chalcogenide structure CS having not gone through the UV treatment (w/o UV) by using the split process, as a comparative example, may be compared to the chalcogenide structure CS having gone through the UV treatment(w/UV) by using the split process, as an embodiment. In an embodiment in which the UV treatment is performed by using the split process, UV treatment for about 10 minutes has been performed at each chalcogenide layer CL deposition a total of six times to form the chalcogenide structure CS having a thickness of about 30 nm.

Referring to FIG. 11, the memory window of the comparative example has been identified as about 1.11 V, and in particular, the memory window in a tail area has been identified as about 0.57 V. The memory window of the embodiment has been identified as about 1.24 V, and in particular, the memory window in the tail area has been identified as about 0.86 V. It is identified that both the memory window in the embodiment and the memory window in the tail area have greater values than those in the comparative example. In other words, errors during the read operation in the embodiment may be relatively reduced compared to those in the comparative example.

FIG. 12A is a graph of measurement results of drift characteristics of the comparative example at room temperature, and FIG. 12B is a graph of measurement results of drift characteristics of the embodiment at room temperature.

Because drift occurs in the set operation having a relatively low threshold voltage, the threshold voltage may gradually increase over time. In this case, because the increased threshold voltage during the set operation overlaps the threshold voltage of the reset operation, and it is impossible to distinguish between the set operation and the reset operation, an operation failure phenomenon may occur. The time taken until the operation failure phenomenon occurs may be referred to as a retention time.

In FIG. 12A, the slope of the graph of the threshold voltage change amount with respect to the standby time in the set operation in the comparative example is about 63.13 mV/dec, the slope of the graph of the threshold voltage change amount with respect to the standby time in the reset operation in the comparative example is about 75.70 mV/dec, and thus the retention time may be identified as about 0.3 years to about 1 year. In FIG. 12B, the slope of the graph of the threshold voltage change amount with respect to the standby time in the set operation in the embodiment is about 53.31 mV/dec, the slope of the graph of the threshold voltage change amount with respect to the standby time in the reset operation in the embodiment is about 61.75 mV/dec, and thus the retention time may be identified as about 15 years to about 17 years. As a result, it may be identified that the retention time in the embodiment is relatively longer than that in the comparative example, and thus the reliability of data may be secured for a relatively long time.

FIG. 13A is a graph of measurement results of drift characteristics in the comparative example at about 86° C., and FIG. 13B is a graph of measurement results of drift characteristics in the embodiment at 85° C.

In FIG. 13A, the slope of the graph of the threshold voltage change amount with respect to the standby time in the set operation in the comparative example is about 65.14 mV/dec, the slope of the graph of the threshold voltage change amount with respect to the standby time in the reset operation in the comparative example is about 73.82 mV/dec, and thus the retention time may be identified as about 0.5 days to about 2 days. In FIG. 13B, the slope of the graph of the threshold voltage change amount with respect to the standby time in the set operation in the embodiment is about 49.37 mV/dec, the slope of the graph of the threshold voltage change amount with respect to the standby time in the reset operation in the embodiment is about 69.92 mV/dec, and thus the retention time may be identified as about 3 years to about 4 years. As a result, it may be identified that the retention time in the embodiment is relatively longer than that in the comparative example, and thus the reliability of data may be secured for a relatively long time. In addition, both the experiment at room temperature and the experiment at high temperature have identified that the retention time in the embodiment is relatively longer than that in the comparative example.

FIG. 14A is a graph of read disturb characteristics in the comparative example, and FIG. 14B is a graph of read disturb characteristics in the embodiment. The corresponding graphs are results measured by using an oscilloscope, and after the write operation is performed once by applying a square pulse of about 1 microsecond and about 6 V, the read operation has been performed by repeatedly applying a square pulse of about 100 nanoseconds and about 3 V.

Referring to FIG. 14A, in the comparative example, the read disturb has appeared when the number of reads is about 10⁷ times to about 10⁸ times, and in the embodiment, the read disturb has appeared when the number of reads is about 10⁸ times to about10⁹ times. In other words, it has been identified that the probability of the read disturb occurring in the embodiment is about 10 times to about 100 times less than that in the comparative example.

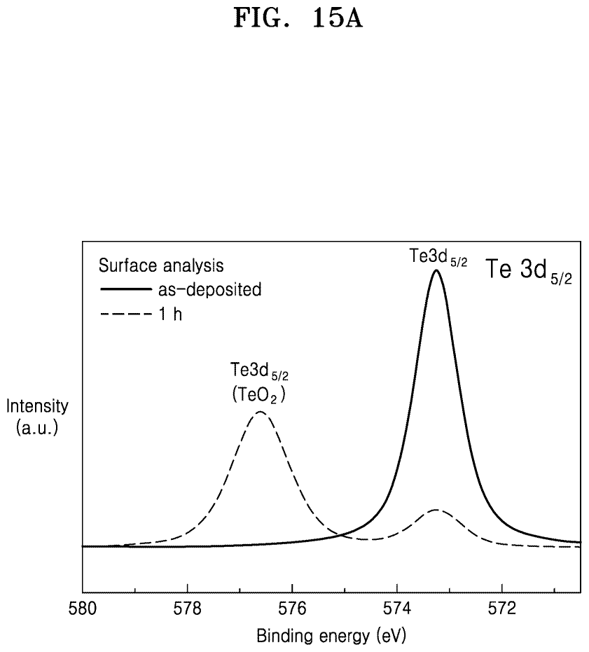

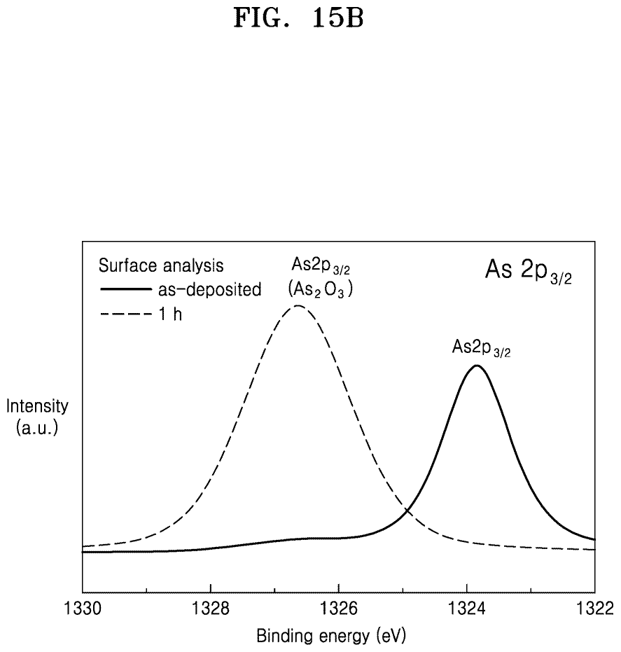

FIGS. 15A and 15B are diagrams of changes in material characteristics on a surface when the UV treatment is performed for a relatively long time.

FIGS. 15A and 15B are X-ray photoelectron spectroscopy (XPS) analysis graphs observed on the surface of the chalcogenide structure CS. A comparative example (as-deposited) including the chalcogenide structure CS formed without performing the UV treatment and an embodiment (1 h) including the chalcogenide structure CS formed by performing the UV treatment for 1 hour are separately shown. In the embodiment with the UV treatment, the chalcogenide structure CS has been formed by performing the UV treatment on the surface of the chalcogenide structure CS having a thickness of about 30 nm without a split process for about 1 hour.

Referring to FIGS. 15A and 15B, in the binding energy graphs obtained by observing Te 3d_{5/2} and As 2p_{3/2} in the comparative example (as-deposited) and the embodiment (1 h), it is identified that the binding energy values at peaks have been greatly changed. The result may be caused by a change in the binding of a material on the surface of the chalcogenide structure CS, and when the UV treatment is performed for a relatively long time, it is identified that the binding of the material on the surface changes.

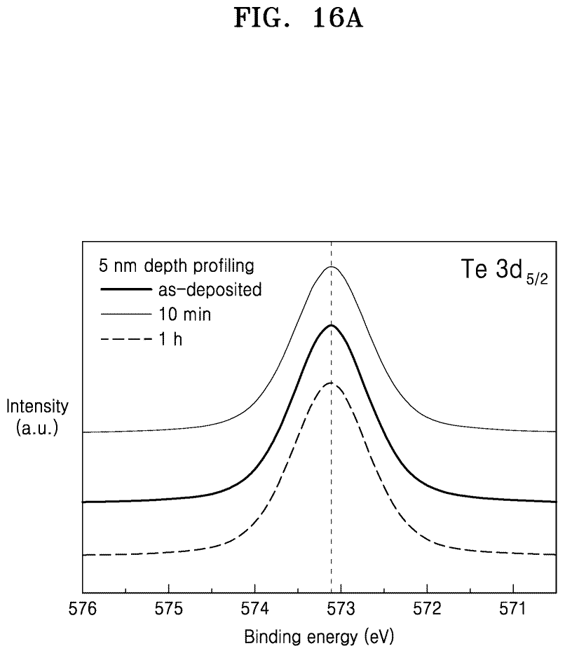

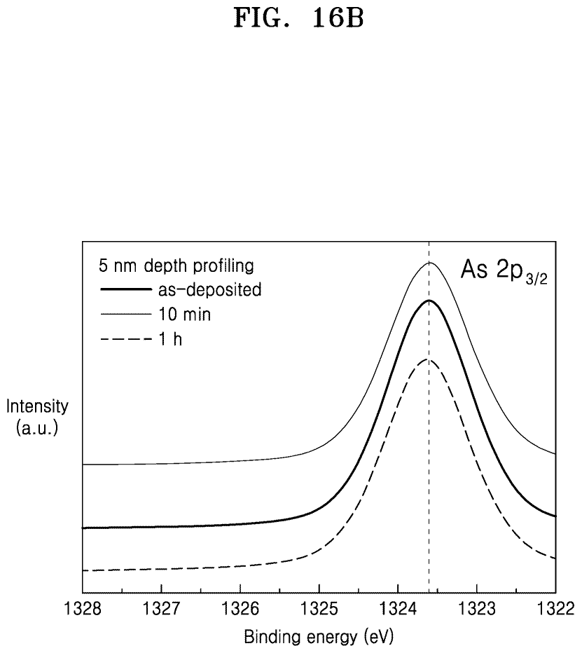

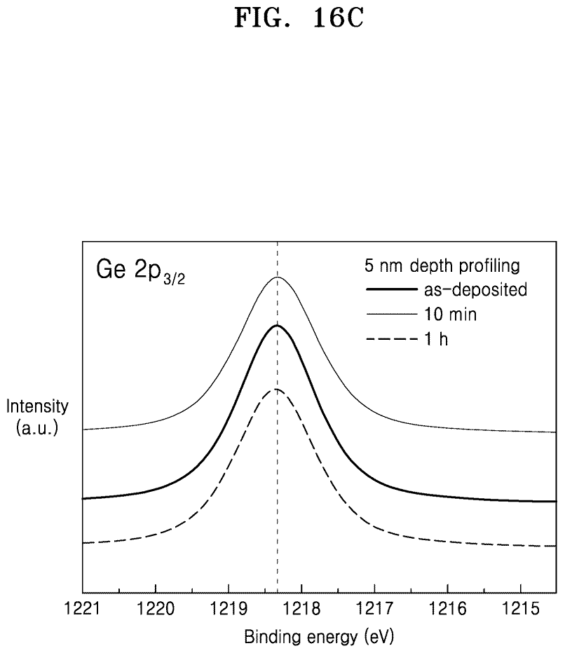

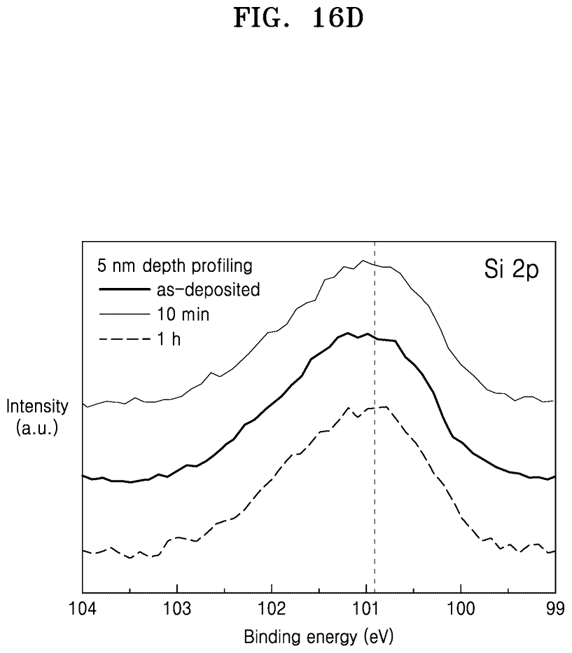

FIGS. 16A, 16B, 16C, and 16D are diagrams of changes in material characteristics inside the chalcogenide structure CS in cases where the UV treatment is performed for a relatively long time and a relatively short time.

FIGS. 16A through 16D are X-ray optoelectronic analysis graphs with about 5 nm depth profiling in the chalcogenide structure CS. A comparative example (as-deposited) in which the chalcogenide structure CS has been formed without performing the UV treatment, a first embodiment (10 min) in which the chalcogenide structure CS has been formed by performing the UV treatment for 10 minutes, and a second embodiment (1 h) in which the chalcogenide structure CS has been formed by performing the UV treatment for 1 hour are shown. In the first embodiment or the second embodiment in which the UV treatment has been performed, the chalcogenide structure CS has been formed by performing the UV treatment without the split process on the surface of the chalcogenide structure CS having a thickness of about 30 nm for about 10 minutes or about 1 hour.

Referring to FIGS. 16A through 16D, in the binding energy graphs obtained by observing Te 3d_{5/2}, As 2p_{3/2}, Ge 2p_{3/2}, and Si 2p in the comparative example (as-deposited) and the embodiment (1 h), it is identified that the binding energy values at peaks have not been greatly changed. The result may mean that, referring to FIGS. 15A and 15B together, the binding of the material on the surface of the chalcogenide structure CS changes when the UV treatment is performed on the chalcogenide structure CS, but the binding of the material inside the chalcogenide structure CS does not change. Accordingly, to significantly improve electrical characteristics by changing the interatomic bonding by using the UV treatment on the chalcogenide structure CS, the split process, in which the chalcogenide layer CL is deposited at a small thickness and the UV treatment process is repeatedly performed on the chalcogenide layer CL to form the chalcogenide structure CS, may be required by necessity.

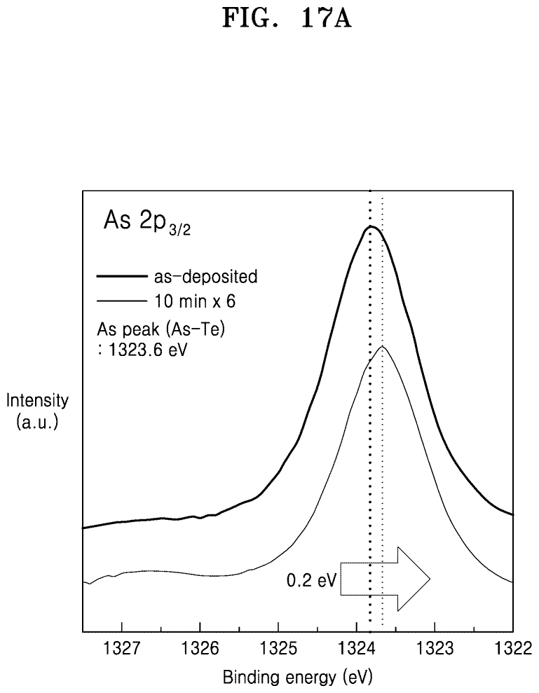

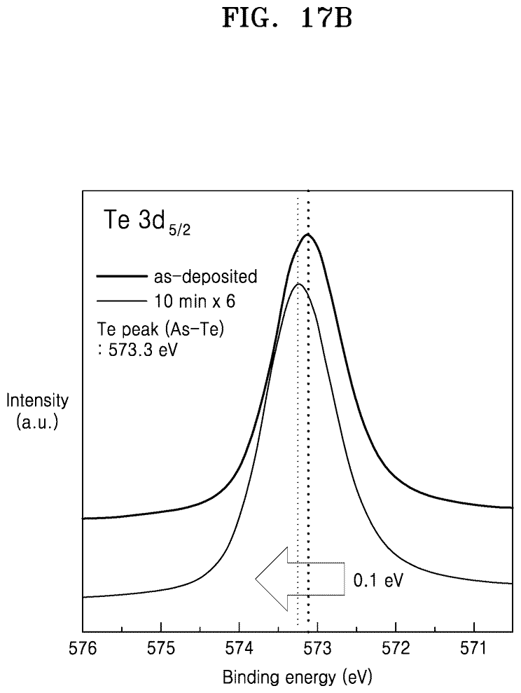

FIGS. 17A and 17B are diagrams of a binding energy increase of the chalcogenide structure CS, according to embodiments.

The chalcogenide structure CS having not gone through the UV treatment (as-deposited) by using the split process, as a comparative example, may be compared to the chalcogenide structure CS having gone through the UV treatment (10 min×6) by using the split process, as an embodiment. In an embodiment in which the UV treatment is performed by using the split process, UV treatment for about 10 minutes has been performed at each chalcogenide layer CL deposition a total of six times to form the chalcogenide structure CS having a thickness of about 30 nm.

FIG. 17A is an X-ray optoelectronic analysis graph of As 2p_{3/2} on the surface of the chalcogenide structure CS, and illustrates the binding energy graph of As, and FIG. 17B is an X-ray optoelectronic analysis graph of Te 3d_{5/2} on the surface of the chalcogenide structure CS, and illustrates the binding energy graph of Te. Elements constituting the chalcogenide structure, arsenide (As), tellurium (Te), germanium (Ge), and silicon (Si), may have electronegativity of 2.18, 2.10, 2.01, and 1.90, respectively. Thus, the electronegativity may decrease in the order of As, Te, Ge, and Si.

The binding energy value at the peak of the X-ray optoelectronic analysis graph illustrated in FIG. 17A shows that the As binding energy in the embodiment is less than that in the comparative example, and the binding energy value at the peak of the X-ray optoelectronic analysis graph illustrated in FIG. 17B shows that the Te binding energy in the embodiment is greater than that in the comparative example. In FIG. 17A, that the bonding energy of As having strong electronegativity decreases may be due to the fact that the existing As—As bond is broken and As is bonded with Te having weak electronegativity to form an As—Te bond. In FIG. 17B, that the bonding energy of Te having weak electronegativity increases may be due to the fact that the existing Te—Te bond is broken and Te is bonded with As, that has strong electronegativity, to form the As—Te bond. In the As—Te bond, electrons may be biased toward As, which has a relatively stronger electronegativity than Te, the binding energy of As may decrease, and the binding energy of Te may increase.

The As—Te bond may be a heteropolar bond between elements having a difference in electronegativity, and may have more stability than a homopolar bond between elements having no difference in electronegativity, such as an As—As bond and a Te—Te bond. Thus, the binding energy in the embodiment may be increased due to the increase in As—Te bonding, compared to the binding energy in the comparative example, which may cause a change in electrical characteristics in the embodiment described above.

In addition, referring to FIGS. 16A through 16D together, because in the X-ray optoelectronic analysis graph of As 2p_{3/2} inside the chalcogenide structure CS (for example, at about 5 nm depth), the binding energy values at the peaks in the comparative examples (as-deposited) without the UV treatment and the binding energy values at the peaks in the embodiments (10 min and 1 h) having gone through the UV treatment without the split process have been shown to be substantially the same, it may be inferred that because the UV treatment does not affect the inside of the chalcogenide structure CS, the As—Te bonding does not increase, and the binding energy value of As does not decrease.

Thus, it may be inferred that the binding energy value at the peak of the X-ray optoelectronic analysis graph of As 2p_{3/2} is less on the surface of the chalcogenide structure CS than inside the chalcogenide structure CS (however, the surface thereof is omitted). In addition, it may be inferred that the number of As—Te bonds on the surface of the chalcogenide structure CS is different from that inside the chalcogenide structure CS, and the number of As—Te bonds on the surface of the chalcogenide structure CS is greater than that inside the chalcogenide structure CS.

In addition, referring to FIGS. 16A through 16D together, because in the X-ray optoelectronic analysis graph of Te 3d_{5/2} inside the chalcogenide structure CS, the binding energy values at the peaks in the comparative examples (as-deposited) without the UV treatment on the chalcogenide structure CS and the binding energy values at the peaks in the embodiments (10 min and 1 h) having gone through the UV treatment have been shown to be substantially the same, it may be inferred that because the UV treatment does not affect the inside of the chalcogenide structure CS, the As—Te bonding does not increase, and the binding energy value of Te does not increase.

Thus, it may be inferred that the binding energy value at the peak of the X-ray optoelectronic analysis graph of Te 3d_{5/2} is greater on the surface of the chalcogenide structure CS than inside the chalcogenide structure CS.

The descriptions given above of the bonding between atoms on the surface of a UV-treated chalcogenide structure CS may be equally applied to the bonding between atoms on the surface of the chalcogenide layer CL.

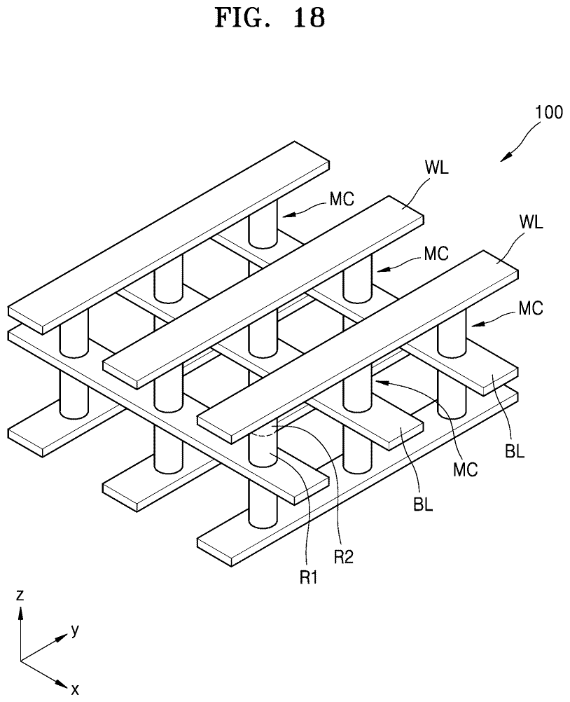

FIG. 18 is a schematic perspective view of a structure of the memory device 100, according to an embodiment.

Referring to FIG. 18, the memory device 100 may have a three-dimensional cross-point structure. For example, the memory device 100 may include a plurality of bit lines BL extending in a first direction (that is, x-axis direction), a plurality of word lines WL extending in a second direction (that is, y-axis direction) crossing the first direction, and a plurality of memory cells MC provided at points where the plurality of bit lines BL respectively cross the plurality of word lines WL. Each of the plurality of memory cells MC may have a rod shape, and may correspond to the chalcogenide structure CS of the memory device 10 illustrated in FIG. 1. Accordingly, each of the plurality of memory cells MC may have the same characteristics as the chalcogenide structure CS of the memory device 10 illustrated in FIG. 1. In addition, each of the plurality of bit lines BL may correspond to the first electrode LE of the memory device 10 illustrated in FIG. 1, and each of the plurality of word lines WL may correspond to the second electrode UE of the memory device 10 illustrated in FIG. 1. Although omitted in FIG. 18, a component corresponding to the first buffer layer BF1 of FIG. 1 may be arranged between each of the plurality of bit lines BL and each of the plurality of memory cells MC, and a component corresponding to the second buffer layer BF2 may be arranged between each of the plurality of word lines WL and each of the plurality of memory cells MC.

In this structure, the memory cell MC may be driven by a potential difference between the word line WL and the bit line BL, which are respectively connected to both ends of each memory cell MC.

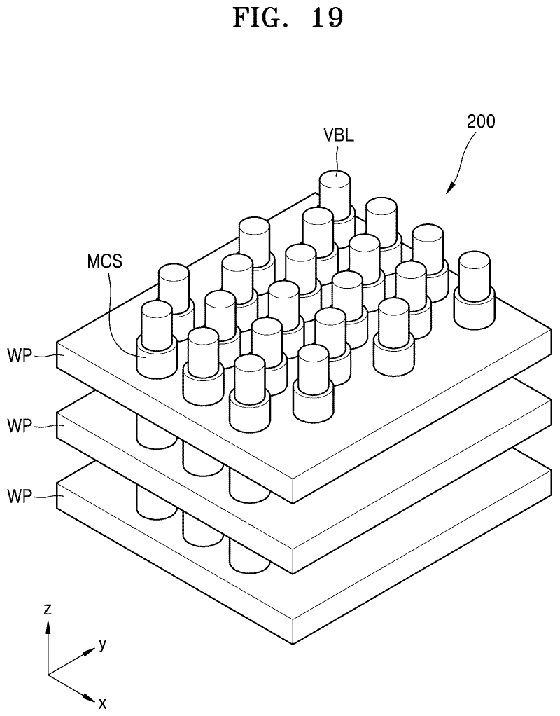

FIG. 19 is a schematic perspective view of a structure of a memory device 200, according to another embodiment.

Referring to FIG. 19, the memory device 200 may include a plurality of word planes WP extending along a plane including the first direction and the second direction and being apart from each other in a third direction (that is, z-axis direction) crossing the first direction and the second direction, a plurality of vertical bit lines VBL extending in the third direction and two-dimensionally arranged in the first direction and the second direction, and a plurality of memory cell strings MCS surrounding surfaces of the plurality of vertical bit lines VBL and extending in the third direction. Like the plurality of vertical bit lines VBL, the plurality of memory cell strings MCS may be two-dimensionally arranged in the first direction and the second direction. Each of the plurality of memory cell strings MCS and each of the plurality of vertical bit lines VBL may be arranged to penetrate the plurality of word planes WP in the third direction. Because each of the plurality of memory cell strings MCS extends in a vertical direction, the memory device 200 illustrated in FIG. 19 may be referred to as a vertical memory device, and may have a further improved memory capacity. Each of the plurality of memory cell strings MCS may have the same material as the chalcogenide structure CS of the memory device 10 illustrated in FIG. 1.

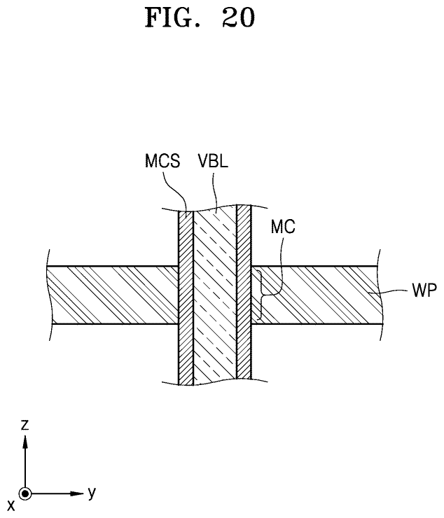

FIG. 20 is a schematic vertical cross-section view of a configuration of one memory cell MC in the memory device 200 illustrated in FIG. 19.

Referring to FIG. 20, an area surrounded by one word plane WP in each of the plurality of memory cell strings MCS extending in the third direction may form one memory cell MC. Accordingly, one memory cell string MCS may include the plurality of memory cells MC arranged apart from each other in the third direction. Each memory cell MC may correspond to the chalcogenide structure CS of the memory device 10 illustrated in FIG. 1, and may have the same characteristics as the chalcogenide structure CS of the memory device illustrated in FIG. 1.

While the present disclosure has been particularly shown and described with reference to embodiments thereof, it will be understood that various change in form and details may be made therein without departing from the spirit and scope of the following claims.

What is claimed is:

1. A method of manufacturing a memory device, the method comprising:
preparing a first electrode;
forming a chalcogenide structure on the first electrode; and
forming a second electrode on the chalcogenide structure,
wherein the forming of the chalcogenide structure comprises:
depositing a chalcogenide layer to form a deposited chalcogenide layer; and
performing an ultraviolet treatment on the deposited chalcogenide layer, and
wherein the depositing of the chalcogenide layer and the performing of the ultraviolet treatment are repeatedly performed until the chalcogenide structure has a predetermined thickness.

2. The method of claim 1, further comprising, before the forming of the chalcogenide structure on the first electrode, forming a first buffer layer on the first electrode.

3. The method of claim 1, further comprising, before the forming of the second electrode on the chalcogenide structure, forming a second buffer layer on the chalcogenide structure.

4. The method of claim 1, further comprising:
before the forming of the chalcogenide structure on the first electrode, forming a first buffer layer on the first electrode; and
before the forming of the second electrode on the chalcogenide structure, forming a second buffer layer on the chalcogenide structure.

5. The method of claim 4, wherein the first buffer layer and the second buffer layer comprise carbon.

6. The method of claim 1, wherein the ultraviolet treatment is performed for about 5 minutes to about 30 minutes.

7. The method of claim 1, wherein the ultraviolet treatment is performed by using a light source of about 900 W to about 1100 W within an ultraviolet wavelength range.

8. The method of claim 1, wherein the chalcogenide layer has a thickness of about 0.1 nm to about 10 nm in a direction in which the second electrode is stacked on the first electrode.

9. The method of claim 1, wherein
the chalcogenide layer comprises one material of GeAsSe, GeAsSeIn, GeAsSeSb, GeAsSeSbIn, GeAsSeTe, GeAsSeIn, GeAsSeAl, GeAsSeAlIn, GeSbSe, GeSbSeIn, GeSbSeN, and GeSbSeNIn.

10. The method of claim 1, wherein a number of As—Te bonds on a surface of the chalcogenide layer is different from a number of As—Te bonds inside the chalcogenide layer.

11. A method of manufacturing a memory device, the method comprising:
preparing a first electrode;
forming a first buffer layer on the first electrode;
forming a chalcogenide structure having ovonic threshold switching characteristics on the first buffer layer;
forming a second buffer layer on the chalcogenide structure; and
forming a second electrode on the second buffer layer,
wherein the forming of the chalcogenide structure comprises:
depositing a chalcogenide layer to form a deposited chalcogenide layer; and
performing an ultraviolet treatment on the deposited chalcogenide layer, and
wherein the depositing of the chalcogenide layer and the performing of the ultraviolet treatment are repeatedly performed until the chalcogenide structure has a predetermined thickness.

12. The method of claim 11, wherein
each of the first electrode and the second electrode independently comprises titanium nitride (TiN), titanium silicon nitride (TiSiN), titanium carbon nitride (TiCN), titanium carbon silicon nitride (TiCSiN), titanium aluminum nitride (TiAlN), tantalum (Ta), tantalum nitride (TaN), tantalum silicon nitride (TaSiN), tantalum aluminum nitride (TaAlN), tungsten silicon (WSi), titanium tungsten (TiW), molybdenum nitride (MoN), niobium nitride (NbN), titanium niobium nitride (TiNbN), zirconium silicon nitride (ZrSiN), tungsten silicon nitride (WSiN), tungsten boron nitride (WBN), zirconium aluminum nitride (ZrAlN), molybdenum aluminum nitride (MoAlN), titanium aluminum (TiAl), titanium oxynitride (TiON), titanium aluminum oxynitride (TiAlON), tungsten oxynitride (WON), tantalum oxynitride (TaON), silicon carbon (SiC), silicon carbon nitride (SiCN), carbon nitride (CN), tantalum carbon nitride (TaCN), tungsten (W), tungsten nitride (WN), carbon (C), or a combination thereof, and
wherein the first buffer layer and the second buffer layer comprise C.

13. The method of claim 11, wherein the ultraviolet treatment is performed by using a light source of about 900 W to about 1100 W within an ultraviolet wavelength range for about 5 minutes to about 30 minutes.

14. The method of claim 11, wherein the chalcogenide layer has a thickness of about 0.1 nm to about 10 nm in a direction in which the second electrode is stacked on the first electrode.

15. The method of claim 11, wherein
the chalcogenide layer comprises one material of GeAsSe, GeAsSeIn, GeAsSeSb, GeAsSeSbIn, GeAsSeTe, GeAsSeIn, GeAsSeAl, GeAsSeAlIn, GeSbSe, GeSbSeIn, GeSbSeN, and GeSbSeNIn.

16. The method of claim 11, wherein a number of As—Te bonds on a surface of the chalcogenide layer is different from a number of As—Te bonds inside the chalcogenide layer.

17. The method of claim 16, wherein the number of As—Te bonds on a surface of the chalcogenide layer is greater than the number of As—Te bonds inside the chalcogenide layer.

18. The method of claim 11, wherein,
at peaks of an X-ray optoelectronic analysis graph of a particular atom on a surface of the chalcogenide layer,
a binding energy value on the surface of the chalcogenide layer is different from a binding energy value inside the chalcogenide layer.

19. A method of manufacturing a memory device, the method comprising:
preparing a first electrode;
forming a first buffer layer on the first electrode;
forming a chalcogenide structure on the first buffer layer;
forming a second buffer layer on the chalcogenide structure; and
forming a second electrode on the second buffer layer,
wherein the chalcogenide structure comprises a plurality of chalcogenide layers, and
each of the plurality of chalcogenide layers is ultraviolet treated and has a thickness of about 0.1 nm to about 10 nm in a direction in which the second electrode is stacked on the first electrode.

20. The method of claim 19,
wherein, in an interatomic bonding of each of the plurality of chalcogenide layers, a number of heteropolar bonds on a surface of each of the plurality of chalcogenide layers is greater than a number of heteropolar bonds inside each of the plurality of chalcogenide layers.
